(19) United States
(12) Patent Application Publication
(10) Pub. No.: US 2012/0171801 A1
(43) Pub. Date: Jul. 5, 2012

(54) SILICONE MEMBRANE FOR LAMINATION PROCESS

(75) Inventors: Steven R. Jette, Auburn, MA (US); James Holtzinger, Cohoes, NY (US); Senthil K. Jayaseelan, Troy, NY (US)

(73) Assignee: SAINT-GOBAIN PERFORMANCE PLASTICS CORPORATION, Aurora, OH (US)

(21) Appl. No.: 13/341,880

(22) Filed: Dec. 30, 2011

Related U.S. Application Data
(60) Provisional application No. 61/428,782, filed on Dec. 30, 2010.

(51) Int. Cl. H01L 31/18; B32B 3/00; B32B 37/06

(52) U.S. Cl. 438/64; 156/499; 428/220

(57) ABSTRACT

A membrane includes a blend of a silicone polymer and not greater than 25 wt % of an elastomeric component. The membrane has a thickness of at least 1 mm and exhibits a tensile retention index of at least 35%.

### CROSS-REFERENCE TO RELATED APPLICATION(S)

The present application claims priority from U.S. provisional patent application No. 61/428,782, filed Dec. 30, 2010, entitled “IMPROVED SILICONE MEMBRANE FOR LAMINATION PROCESS,” naming inventors Steven R. Jette, James Holtzinger and Senthil K. Jayaseelan, which application is incorporated by reference herein in its entirety.

### FIELD OF THE DISCLOSURE

This disclosure, in general, relates to membranes for use in lamination equipment and methods for using such membranes.

### BACKGROUND

With concern over energy policy and the environment, industry is turning to alternative energy sources such as wind power and solar power. In particular, industry is turning to solar power technologies such as photovoltaic technologies. However, conventional photovoltaic systems suffer from long payback periods. Early damage or failure of such conventional photovoltaic devices can make such solar power technologies economically unfeasible.

Attempts have been made to reduce the impact of environmental factors on the life span of photovoltaic devices by coating or encapsulating such photovoltaic devices in polymer films. Such polymer films can also provide impact resistance and other mechanical properties that improve the useable lifespan of conventional photovoltaic devices.

To apply such polymer films and encapsulants to the photovoltaic components, films are laminated to the photovoltaic component. Laminators can include a membrane that contacts the layers to be laminated to or to encapsulate the photovoltaic component after the film or encapsulant is heated.

However, such conventional laminators deteriorate rapidly when exposed to particular films that are useful as encapsulants of a photovoltaic component. Over time, the quality and consistency of the lamination suffers. As such, improved photovoltaic film would be desirable.

### BRIEF DESCRIPTION OF THE DRAWINGS

The present disclosure may be better understood, and its numerous features and advantages made apparent to those skilled in the art by referencing the accompanying drawings.

FIG. 1 includes an illustration of an exemplary laminator device.

FIG. 2 includes an illustration of an exemplary multilayer film.

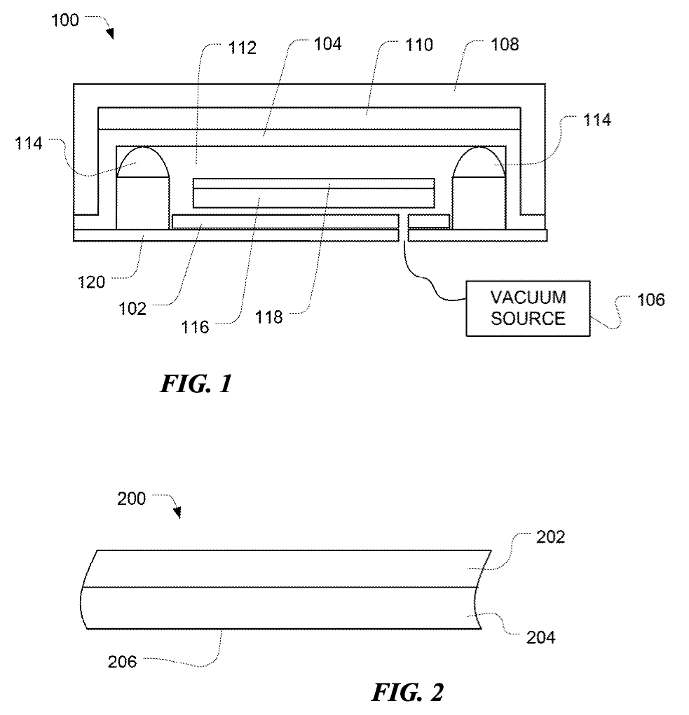

The use of the same reference symbols in different drawings indicates similar or identical items.

### DETAILED DESCRIPTION

In an embodiment, a laminator includes a heat source and a membrane disposed to contact an article being laminated. It has been discovered that outgas sing and volatilization of particularly corrosive byproducts leads to reduced performance of the membrane within the laminator. Such reduced performance by the membrane can lead to poor quality lamination of the encapsulant to the photovoltaic component. In another example, it has been found that the decrease in properties of the membrane leads to more frequent replacement of the membrane and thus, greater expense to a laminating facility. Given the price pressure on photovoltaic components in an open energy market, such added costs lead to a decrease in economic feasibility of photovoltaic technologies.

In an example, a laminator 100 includes a heat source 102 and a membrane 104. The laminator 100 can also include a vacuum source 106. The membrane 104 is secured to a support, such as upper support 108, and forms a volume 112 in cooperation with seals 114 and a second support, such as lower support 120. While the membrane 104 is illustrated as being coupled to an upper support 108, other configurations can be envisaged. In the illustrated laminator 100, a volume 110 is formed between the upper support 108 and the membrane 104.

In an example, the heat source 102 can be a heated platen or pad disposed on a lower support 120, such as within the volume 112 as illustrated. In another example, the heat source 102 can be outside of the chamber, such as below the lower support 120.

In practice, a photovoltaic component 116 is placed in the volume 112 and a film 118 to be laminated over the photovoltaic component 116 is positioned in contact with the photovoltaic component 116. While the film 118 is illustrated as being over the photovoltaic component 116, one or more films can be place over or under the photovoltaic component 116 as desired.

A vacuum is drawn in both the volume 112 and the volume 110 while the photovoltaic component 116 and the film 118 are heated using the heat source 102. Once the film is sufficiently softened, the vacuum is release in the volume 110, increasing the pressure in the volume 110 and motivating the membrane 104 against the film 118 and photovoltaic component 116. As a result, the film 118 is laminated to the photovoltaic component 116. Following lamination, the vacuum can be released from the volume 112 and the laminated photovoltaic device removed from the laminator 100.

While the supports 108 and 120 are illustrated in cross-section, other strengthening elements, such as cross-beams and I-beams can be provided on the supports to provide additional structural integrity. Alternative laminators can be envisaged that include volumes of different shapes or that provide other methods of motivating the membrane to contact the photovoltaic device components.

The membrane 104 can be formed of a silicone polymer, a silicone/elastomer blend, or any combination thereof. In particular, the silicone formulation includes crosslinked silicone polymers. The silicone polymer may, for example, include polyalkylsiloxanes, such as silicone polymers formed of a precursor, such as dimethylsiloxane, diethylsiloxane, dipropylsiloxane, methylethylsiloxane, methylpropylsiloxane, or any combination thereof. In an example, the polyalkylsiloxane includes a polydialkylsiloxane, such as polydimethylsiloxane (PDMS). In a particular example, the polyalkylsiloxane is a silicone hydride-containing polydimethylsiloxane. In a further embodiment, the polyalkylsiloxane is a vinyl-containing polydimethylsiloxane.

In another example, the silicone polymer is a combination of a hydride-containing polydimethylsiloxane and a vinyl-containing polydimethylsiloxane. In an example, the silicone polymer is non-polar and is free of halide functional groups, such as chlorine and fluorine, and of phenyl functional groups. Alternatively, the silicone polymer can include halide functional groups or phenyl functional groups. For example, the silicone polymer can include fluorosilicone or phenylsilicone. Suitable silicone polymers as described in the art include MQ silicone polymers having only methyl groups on the polymer chain; VMQ silicone polymers having methyl and vinyl groups on the polymer chain; PMQ silicone polymers having methyl and phenyl groups on the polymer chain; PVMQ silicone polymers having methyl, phenyl and vinyl groups on the polymer chain; and FVMQ silicone polymers having methyl, vinyl and fluoro groups on the polymer chain. Particular embodiments of these elastomers include the Silastic® silicone elastomers from Dow Corning or the like.

The silicone formulation can further include a catalyst and other optional additives. Exemplary additives can include, individually or in combination, fillers, inhibitors, colorants, or pigments. In an embodiment, the silicone formulation is a platinum catalyzed silicone formulation. Alternatively, the silicone formulation can be a peroxide cured silicone formulation. In another example, the silicone formulation can be a combination of a platinum catalyzed and peroxide cured silicone formulation. The silicone formulation can be a room temperature vulcanizable (RTV) formulation or a gel. In an example, the silicone formulation can be a liquid silicone rubber (LSR) or a high consistency gum rubber (HCR). In a particular example, the silicone formulation is a platinum catalyzed LSR. In a further example, the silicone formulation is an LSR formed from a two-part reactive system. Alternatively, the silicone formulation is an HCR silicone.

The silicone formulation can be a conventional, commercially prepared silicone polymer. The commercially prepared silicone polymer typically includes the non-polar silicone polymer, a catalyst, a filler, and optional additives. “Conventional” as used herein refers to a commercially prepared silicone polymer that is free of any self-bonding moiety or additive. Particular embodiments of conventional, commercially prepared LSR include Wacker Elastosil® LR 3003/50 by Wacker Silicone of Adrian, Mich. and Rhodia Silbione® LSR 4340 by Rhodia Silicones of Ventura, Calif. In another example, the silicone polymer is an HCR, such as Wacker Elastosil® R4000/50 available from Wacker Silicone, or HS-50 High Strength HCR available from Dow Corning.

In an example, a conventional, commercially prepared silicone polymer is available as a two-part reactive system. Part 1 typically includes a vinyl-containing polydialkylsiloxane, a filler, and catalyst; part 2 typically includes a hydride-containing polydialkylsiloxane and optionally, a vinyl-containing polydialkylsiloxane or other additives. A reaction inhibitor can be included in Part 1 or Part 2. Mixing Part 1 and Part 2 by any suitable mixing method produces the silicone formulation. In an exemplary embodiment, the two-part system are mixed in a mixing device. In an example, the mixing device is a mixer in an injection molder. In another example, the mixing device is a mixer, such as a dough mixer, Ross mixer, two-roll mill, or Brabender mixer.

The silicone can be blended with an elastomeric component. For example, the elastomeric component can include a butyl elastomer, diene elastomer, a nitrile elastomer, a fluorinated elastomer, a fluorosilicone elastomer, elastomeric block copolymers, or any combination thereof. The nitrile elastomer can include nitrile rubber (NBR), hydrogenated nitrile rubber (HNBR), or any combination thereof. A butyl elastomer includes butyl rubber. A fluorosilicone rubber includes a fluorine substituted silicone rubber, such as a fluorinated derivative of the silicone rubbers described above.

Among the useful elastomers are elastomeric block copolymers, such as styrene-butadiene (SB), styrene-butadiene-styrene (SBS), styrene-isoprene-styrene (SIS), styrene-isoprene (SI), styrene-ethylenebutylene-styrene (SEBS), styrene-ethylene-butylene (SEB) styrene-ethylene-propylene-styrene (SEPS), isoprene-isobutylene rubbers (UR) styrene-ethylene-propylene (SEP), acrylonitrile-butadiene-styrene (ABS), or any combination thereof.

Among the useful elastomers are ethylene propylene rubber (EPR), EPDM rubber or blends of EPR and EPDM. An exemplary diene elastomer is a copolymer formed from at least one diene monomer. For example, the diene elastomer can be a copolymer of ethylene, propylene and diene monomer (EPDM). An exemplary diene monomer includes a conjugated diene, such as butadiene, isoprene, chloroprene, or the like; a non-conjugated diene including from 5 to about 25 carbon atoms, such as 1,4-pentadiene, 1,4-hexadiene, 1,5-hexadiene, 2,5-dimethyl-1,5-hexadiene, 1,4-octadiene, or the like; a cyclic diene, such as cyclopentadiene, cyclohexadiene, cyclooctadiene, dicyclopentadiene, or the like; a vinyl cyclic ene, such as 1-vinyl-1-cyclopentene, 1-vinyl-1-cyclohexene, or the like; an alkylbicyclononadiene, such as 3-methylbicyclo-(4,2,1)-nona-3,7-diene, or the like; an indene, such as methyl tetrahydroindene, or the like; an alkenyl norbornene, such as 5-ethylidene-2-norbornene, 5-butylidene-2-norbornene, 2-methallyl-5-norbornene, 2-isopropenyl-5-norbornene, 5-(1,5-hexadienyl)-2-norbornene, 5-(3,7-octadienyl)-2-norbornene, or the like; a tricyclodiene, such as 3-methyltricyclo (5,2,1,0²,6)-deca-3,8-diene or the like; or any combination thereof. In a particular embodiment, the diene includes a non-conjugated diene. In another embodiment, the diene elastomer includes alkenyl norbornene. The diene elastomer can include, for example, ethylene from about 63 wt % to about 95 wt % of the polymer, propylene from about 5 wt % to about 37 wt %, and the diene monomer from about 0.2 wt % to about 15 wt %, based upon the total weight of the diene elastomer. In a particular example, the ethylene content is from about 70 wt % to about 90 wt %, propylene from about 17 wt % to about 31 wt %, and the diene monomer from about 2 wt % to about 10 wt % of the diene elastomer.

An exemplary fluoropolymer can be formed of a homopolymer, copolymer, terpolymer, or polymer blend formed from a monomer, such as tetrafluoroethylene, hexafluoropropylene, chlorotrifluoroethylene, trifluoroethylene, vinylidene fluoride, vinyl fluoride, perfluoropropyl vinyl ether, perfluoromethyl vinyl ether, or any combination thereof. An exemplary fluoropolymer includes polytetrafluoroethylene (PTFE), a fluorinated ethylene propylene copolymer (FEP), a copolymer of tetrafluoroethylene and perfluoropropyl vinyl ether (perfluoroalkoxy or PFA), a copolymer of tetrafluoroethylene and perfluoromethyl vinyl ether (MFA), a copolymer of ethylene and tetrafluoroethylene (ETFE), a copolymer of ethylene and chlorotrifluoroethylene (ECTFE), polychlorotrifluoroethylene (PCTFE), poly vinylidene fluoride (PVDF), a terpolymer including tetrafluoroethylene, hexafluoropropylene, and vinylidenefluoride (THV), or any blend or any alloy thereof. In an example, the fluoropolymer is a fluoroelastomer, such as fluorinated ethylene propylene (FEP), perfluoroalkoxy (PFA), polyvinylidene fluoride (PVDF), or any combination thereof. In another example, the fluoroelastomer includes copolymers of vinylidene fluoride and hexafluoropropylene; THV; copolymers of vinylidene fluoride, hexafluoropropylene, tetrafluoroethylene, and perfluoromethyl vinyl ether; copolymers of propylene, tetrafluoroethylene, and vinylidene fluoride; copolymers of vinylidene fluoride, hexafluoropropylene, tetrafluoroethylene, and perfluoromethyl vinyl ether; or any combination thereof.

Any of the elastomeric polymer types described in the preceding paragraphs can be compounded with catalysts or curatives, fillers, pigments, processing aids, flame retardants and other additives. Typical catalysts or curatives for elastomeric compositions include organic peroxides, platinum, palladium, rhodium, ruthenium, organotin catalysts, or any combination thereof. Organic peroxides include di-tert-butyl peroxide, tert-butyl cumyl peroxide, dicumyl peroxide, tert-butyl peroxybenzoate, dibenzoyl peroxide, di-(4-methylbenzoyl)peroxide, di-2,4-dichlorobenzoyl peroxide, or any combination thereof. Suitable organotin catalysts include, for example, dibutyl tin dilaurate, dibutyl tin diacetate, dioctyl tin maleate, organotitanates etc. Thermoplastic elastomers can alternatively be processed without catalysts.

When present in a blend, the elastomeric component can be included in an amount of less than 50 wt %, such as not greater than 25 wt %. For example, the elastomeric component can be included in an amount in a range of 0.1 wt % to 25 wt %, such as in a range of 5 wt % to 25 wt %, or even in a range of 10 wt % to 20 wt %. The silicone polymer of the blend can be included in an amount of at least 50 wt %, such as at least 75 wt %. For example, the silicone can be included in an amount in a range of 75 wt % to 99.9 wt %, such as in a range of 75 wt % to 95 wt %, or even a range of 80 wt % to 90 wt %.

Once formed, the layer including the blend can have a thickness of at least 500 micrometers, such as at least 800 micrometers, or even at least 1 mm. The thickness of the membrane can be at least 1.2 mm, such as at least 1.5 mm, or even at least 2 mm. For example, the membrane can have a thickness in a range of 1 mm to 10 mm, such as a range of 1.5 mm to 7 mm, or even a range of 2 mm to 5 mm.

In an example, the membrane is a single layer membrane including the blend of silicone and elastomer. In an alternative example, a membrane can include more than one layer. For example, as illustrated in FIG. 2, the membrane 200 can include at least two layers (202 and 204 respectively). One layer can be a pure silicone layer and a second layer can include a blend of silicone and other elastomeric components. As illustrated, layer 204 includes a surface 206 that is to contact a film to be laminated to a photovoltaic component, whereas the layer 202 supports the layer 204 and remains out of contact with the film to be laminated. Alternatively, both layers 202 and 204 can be formed of a blend of an elastomeric component and silicone polymer.

In use, the membrane is incorporated in a laminator including a heat source and optionally including a vacuum source. The laminator applies pressure and heat while extracting air from the stacked components to be adhered (e.g., the photovoltaic component and the film encapsulant). It is particularly effective for photovoltaic modules that use a sealing or encapsulant layer of ethylene vinyl acetate (EVA), as these formulations commonly do not cure in the presence of oxygen. Vacuum lamination is also quite effective in applying steady, gentle pressure to the delicate components and connections that can be present within photovoltaic modules. U.S. Pat. No. 4,450,034 provides a description of one type of vacuum laminator, although a variety of configurations can be employed and this is not meant to be a limiting example.

In vacuum laminators used for photovoltaic modules an elastomeric diaphragm (membrane) is used to transmit pressure. In an exemplary configuration, a diaphragm is clamped beneath an upper chamber and held in place by suction, the apparatus is closed, a lower chamber is evacuated, and the upper chamber is allowed to fill with air. The net effect is to push the membrane against the stack to be laminated with gentle pressure. The membrane used is a flexible elastomeric sheet that can readily deform and conform to any irregularities across the module surface so as to even the application of pressure.

The membrane exhibits improved lifespan relative to conventional membranes. As illustrated in the examples below, the membrane can provide improved lifespan to the laminator. Such improvement in lifespan also leads to a reduction in maintenance costs and other factors. For example, the membrane can exhibit a desirable tensile retention index or a desirable elongation retention index. The tensile retention index and the elongation retention index are the tensile strength and elongation-at-break of sample membranes exposed to ethylene-vinyl acetate (EVA) outgases for a period of 4 hours at approximately 250° C., expressed as a percentage of the initial tensile strength or elongation, respectively. The membrane is placed in a fixture over an EVA film and heated to approximately 250° C. and maintained at that temperature for a period of 4 hours. The tensile and elongation properties of the membrane are tested before and after exposure. In a particular example, the membrane exhibits a tensile retention index of at least 35%, such as at least 40%, at least 45%, at least 50%, at least 55% or even at least 60%. The elongation retention index can be at least 30%, such as at least 35%, at least 40%, at least 45%, at least 50%, at least 55% or even at least 60%.

The membrane can exhibit an initial tensile strength of at least 500 psi, such as at least 800 psi, or even at least 1000 psi. Further, the membrane can exhibit an initial elongation of at least 100%, such as at least 200%, at least 300%, or even at least 400%.

### Example

Blends of HCR silicone precursor and nitrile elastomer are prepared to include the nitrile elastomer in an amount of 0% to 25 wt %, in increments of 5 wt %. The blends are cast into membranes. The membranes are tested as described above to determine tensile retention and elongation retention. Samples including the nitrile elastomer exhibit desirable retention indexes. In particular, samples including between 5 wt % and 25 wt % of the nitrile elastomer exhibit desirable properties.

In a first embodiment, a membrane includes a blend of a silicone polymer and not greater than 25 wt % of an elastomeric component. The membrane has a thickness of at least 1 mm and exhibits a tensile retention index of at least 35%.

In an example of the first embodiment, the tensile retention index is at least 45%. For example, the tensile retention index is at least 55%. In another example, the tensile retention index is at least 60%. In an additional example, the membrane exhibits an elongation retention index of at least 30%. For example, the elongation retention index is at least 40%, such as at least 50%.

In a further example of the first embodiment, the elastomeric component includes a butyl elastomer, diene elastomer, a nitrile elastomer, a fluorinated elastomer, a fluorosilicone elastomer, elastomeric block copolymers, or any combination thereof. For example, the elastomeric component includes a nitrile elastomer, such as nitrile rubber (NBR), hydrogenated nitrile rubber (HNBR), or any combination thereof. In another example, the elastomeric component includes a fluoroelastomer. In an additional example, the elastomeric component includes a butyl elastomer. In a further example, the elastomeric component includes an elastomeric block copolymer.

In another example of the first embodiment, the silicone polymer includes dimethylsiloxane, diethylsiloxane, dipropylsiloxane, methylethylsiloxane, methylpropylsiloxane, or any combination thereof.

In an additional example of the first embodiment, the elastomeric component is included in a range of 5 wt % to 25 wt %. For example, the elastomeric component is included in a range of 10 wt % to 20 wt %.

In a second embodiment, a laminator includes first and second supports and a membrane coupled to the first support and defining a volume between the membrane and the second support, The membrane includes a blend of a silicone polymer and not greater than 25 wt % of an elastomeric component. The membrane has a thickness of at least 1 mm and exhibits a tensile retention index of at least 35%. The laminator further includes a heat source to provide heat to a work piece disposed within the volume.

In an example of the second embodiment, the tensile retention index is at least 45%. For example, the tensile retention index is at least 55%, such as at least 60%. In an additional example, the membrane exhibits an elongation retention index of at least 30%. For example, the elongation retention index is at least 40%, such as at least 50%.

In a further example of the second embodiment, the elastomeric component includes a butyl elastomer, diene elastomer, a nitrile elastomer, a fluorinated elastomer, a fluorosilicone elastomer, elastomeric block copolymers, or any combination thereof. For example, the elastomeric component includes a nitrile elastomer, such as nitrile rubber (NBR), hydrogenated nitrile rubber (HNBR), or any combination thereof. In another example, the elastomeric component includes a fluoroelastomer. In an additional example, the elastomeric component includes a butyl elastomer. In a further example, the elastomeric component includes an elastomeric block copolymer.

In another example of the second embodiment, the silicone polymer includes dimethylsiloxane, diethylsiloxane, dipropylsiloxane, methylethylsiloxane, methylpropylsiloxane, or any combination thereof.

In a third embodiment, a method of forming a photovoltaic device includes placing a photovoltaic component and a film to be laminated to the photovoltaic component within a volume defined between a support and a membrane. The membrane includes a blend of a silicone polymer and not greater than 25 wt % of an elastomeric component. The membrane has a thickness of at least 1 mm and exhibits a tensile retention index of at least 35%. The method further includes heating the photovoltaic component and the film with a heat source and applying a vacuum within the volume, motivating the membrane to contact the film.

Note that not all of the activities described above in the general description or the examples are required, that a portion of a specific activity may not be required, and that one or more further activities may be performed in addition to those described. Still further, the orders in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus. Further, unless expressly stated to the contrary, “or” refers to an inclusive- or and not to an exclusive- or. For example, a condition A or B is satisfied by any one of the following: A is true (or present) and B is false (or not present), A is false (or not present) and B is true (or present), and both A and B are true (or present).

Also, the use of “a” or “an” are employed to describe elements and components described herein. This is done merely for convenience and to give a general sense of the scope of the invention. This description should be read to include one or at least one and the singular also includes the plural unless it is obvious that it is meant otherwise.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

After reading the specification, skilled artisans will appreciate that certain features are, for clarity, described herein in the context of separate embodiments, may also be provided in combination in a single embodiment. Conversely, various features that are, for brevity, described in the context of a single embodiment, may also be provided separately or in any subcombination. Further, references to values stated in ranges include each and every value within that range.

1. A membrane comprising a blend of a silicone polymer and not greater than 25 wt % of an elastomeric component, the membrane having a thickness of at least 1 mm and exhibiting a tensile retention index of at least 35%.

2.-4. (canceled)

5. The membrane of claim 1, wherein the membrane exhibits an elongation retention index of at least 30%.

6.-7. (canceled)

8. The membrane of claim 1, wherein the elastomeric component includes a butyl elastomer, diene elastomer, a nitrile elastomer, a fluorinated elastomer, a fluorosilicone elastomer, elastomeric block copolymers, or any combination thereof.

9. The membrane of claim 8, wherein the elastomeric component includes a nitrile elastomer.

10. The membrane of claim 9, wherein the nitrile elastomer includes nitrile rubber (NBR), hydrogenated nitrile rubber (HNBR), or any combination thereof.

11. The membrane of claim 8, wherein the elastomeric component includes a fluoroelastomer.

12. The membrane of claim 8, wherein the elastomeric component includes a butyl elastomer.

13. The membrane of claim 8, wherein the elastomeric component includes an elastomeric block copolymer.

14. The membrane of claim 1, wherein the silicone polymer includes dimethylsiloxane, diethylsiloxane, dipropylsiloxane, methylethylsiloxane, methylpropylsiloxane, or any combination thereof.

15. The membrane of claim 1, wherein the elastomeric component is included in a range of 5 wt % to 25 wt %.

16. (canceled)

17. A laminator comprising:
first and second supports;
a membrane coupled to the first support and defining a volume between the membrane and the second support, the membrane including a blend of a silicone polymer and not greater than 25 wt % of an elastomeric component, the membrane having a thickness of at least 1 mm and exhibiting a tensile retention index of at least 35%; and
a heat source to provide heat to a work piece disposed within the volume.

18.-20. (canceled)

21. The laminator of claim 17, wherein the membrane exhibits an elongation retention index of at least 30%.

22.-23. (canceled)

24. The laminator of claim 17, wherein the elastomeric component includes a butyl elastomer, diene elastomer, a nitrile elastomer, a fluorinated elastomer, a fluorosilicone elastomer, elastomeric block copolymers, or any combination thereof.

25. The laminator of claim 24, wherein the elastomeric component includes a nitrile elastomer.

26. The laminator of claim 25, wherein the nitrile elastomer includes nitrile rubber (NBR), hydrogentated nitrile rubber (HNBR), or any combination thereof.

27. The laminator of claim 24, wherein the elastomeric component includes a fluoroelastomer.

28. The laminator of claim 24, wherein the elastomeric component includes a butyl elastomer.

29. The laminator of claim 24, wherein the elastomeric component includes an elastomeric block copolymer.

30. The laminator of claim 24, wherein the silicone polymer includes dimethylsiloxane, diethylsiloxane, dipropylsiloxane, methylethylsiloxane, methylpropylsiloxane, or any combination thereof.

31. A method of forming a photovoltaic device, the method comprising:
placing a photovoltaic component and a film to be laminated to the photovoltaic component within a volume defined between a support and a membrane, the membrane including a blend of a silicone polymer and not greater than 25 wt % of an elastomeric component, the membrane having a thickness of at least 1 mm and exhibiting a tensile retention index of at least 35%;
heating the photovoltaic component and the film with a heat source; and
applying a vacuum within the volume, motivating the membrane to contact the film.
